(19) United States
(12) Patent Application Publication
(10) Pub. No.: US 2016/0172301 A1
(43) Pub. Date: Jun. 16, 2016

(54) SEMICONDUCTOR DEVICE AND MANUFACTURING METHOD THEREFOR

(71) Applicant: TOYOTA JIDOSHA KABUSHIKI KAISHA, Toyota-shi (JP)

(72) Inventors: Shinya IWASAKI, Toyota-shi (JP); Seiji ARAKAWA, Nisshin-shi (JP)

(73) Assignee: TOYOTA JIDOSHA KABUSHIKI KAISHA, Toyota-shi (JP)

(21) Appl. No.: 14/942,559

(22) Filed: Nov. 16, 2015

(30) Foreign Application Priority Data
Dec. 11, 2014 (JP) 2014-250622

(51) Int. Cl. H01L 23/535; H01L 23/528; H01L 21/768; H01L 23/532

(52) U.S. Cl. CPC H01L 23/535; H01L 23/53266; H01L 23/528; H01L 21/76895; H01L 21/76843; H01L 21/76816

(57) ABSTRACT

A semiconductor device includes a first insulating film located on the semiconductor substrate and including a first contact hole; a contact plug located in the first contact hole; a first surface electrode extending on the first insulating film and the contact plug; a conductive layer; a second insulating film located on the conductive layer and including a second contact hole wider than the first contact hole; a side metal layer covering a corner portion in the second contact hole and configured of a same kind of metal as the contact plug; and a second surface electrode extending on the second insulating film and in the second contact hole, covering the side metal layer, and configured of a different kind of metal from the contact plug. A bonding pad is located in a part of the second surface electrode on the bottom surface of the second contact hole.

### CROSS-REFERENCE TO RELATED APPLICATION

This application claims priority to Japanese Patent Application No. 2014-250622 filed on Dec. 11, 2014, the contents of which are hereby incorporated by reference into the present application.

### TECHNICAL FIELD

A technique disclosed by the specification relates to a semiconductor device and a manufacturing method therefor.

### DESCRIPTION OF RELATED ART

A semiconductor device described in Japanese Patent Application Publication No. 2014-192351 has an insulating film disposed on a surface of a semiconductor substrate. A contact hole is provided in the insulating film. An upper surface of the insulating film and an internal surface of the contact hole are covered with a barrier metal configured of Ti or the like. A contact plug configured of Al or the like is disposed in the contact hole. In the contact hole, the contact plug is connected to the semiconductor substrate via the barrier metal. The barrier metal prevents elements configuring the contact plug from diffusing in the semiconductor substrate under the barrier metal. A surface electrode configured of Al or the like is disposed on the insulating film and the contact plug. A wire is bonded to the surface electrode.

### SUMMARY

When a wire is bonded to a surface electrode, the surface electrode is pulled off from a semiconductor substrate. As a result of this, the surface electrode is likely to be peeled off together with a barrier metal from an insulating film located on an underside of the barrier metal. Therefore, this specification discloses a semiconductor device in which a surface electrode is less liable to be peeled off from a bonding pad.

A semiconductor device disclosed herein comprises a semiconductor substrate, a first insulating film, a contact plug, a first surface electrode, a conductive layer, a second insulating film, a side metal layer and a second surface electrode. The first insulating film is located on the semiconductor substrate and comprises a first contact hole. The contact plug is located in the first contact hole. The first surface electrode extends from a position on the first insulating film to a position on the contact plug. The conductive layer is located above a surface of the semiconductor substrate or in a semiconductor region within the semiconductor substrate. The surface of the semiconductor substrate includes an area on which the first insulating film is located. In a case where the conductive layer is the semiconductor region, the semiconductor region is exposed on the surface of the semiconductor substrate. The second insulating film is located on the conductive layer and comprises a second contact hole having a width wider than that of the first contact hole. The side metal layer covers a corner portion between a side surface of the second contact hole and a bottom surface of the second contact hole. The side metal layer is configured of a same kind of metal as the contact plug. The second surface electrode extends from a position on the second insulating film to a position in the second contact hole, covers the side metal layer, and is configured of a different kind of metal from the contact plug. A bonding pad is located in a part of the second surface electrode on the bottom surface of the second contact hole.

The conductive layer in the foregoing means a layer having conductivity as high as or higher than that of a semiconductor. That is, the conductive layer is a conductor or semiconductor. The conductive layer may be provided in a semiconductor region exposed on a surface of a semiconductor substrate on a side where the first insulating film is disposed. That is, the conductive layer may be a semiconductor layer (i.e., a semiconductor substrate itself) in the semiconductor substrate. The conductive layer may be a wiring pattern or the like provided on the surface of the semiconductor substrate on the side where the first insulating film is disposed. In a case where the conductive layer is provided on the surface of the semiconductor substrate, the conductive layer may be in direct contact with the surface of the semiconductor substrate, or another layer (e.g., an insulating film) may be interposed between the conductive layer and semiconductor substrate. In this specification, the contact plug means a main metallic material disposed in the contact hole. Therefore, in a case where a very thin film (e.g., a barrier metal or the like) covering an internal surface of the first contact hole is present, such a thin film is not a contact plug. The first insulating film and a second insulating film may be connected with each other. That is, the first and second insulating films may be configured of a single insulating film.

In this semiconductor device, the second contact hole has a wider width than that of the first contact hole. Therefore, under the bonding pad (i.e., on the bottom of the second contact hole), the second surface electrode is connected to the conductive layer in a wide range. This renders the second surface electrode less liable to be peeled off when a wire is bonded to the bonding pad (i.e., the second surface electrode). In this semiconductor device, a side metal layer is provided on the corner portion of the second contact hole. Forming the side metal layer in this way makes it possible to form the second surface electrode on the side metal layer to be comparatively flat. Thus, a strength of the second surface electrode can be increased. This also makes the second surface electrode less liable to be peeled off.

Further, a method for manufacturing a semiconductor device is disclosed herein. The method comprises a conductive layer forming process, a first insulating film forming process, a second insulating film forming process, a first contact hole forming process, a second contact hole forming process, a metal layer forming process, a metal layer etching process, a first surface electrode forming process, and a second surface electrode forming process. In the conductive layer forming process, a conductive layer is formed above a surface of a semiconductor substrate or in a semiconductor region in the semiconductor substrate. In a case where the conductive layer is the semiconductor region, the semiconductor is exposed on the surface of the semiconductor substrate. In the first insulating film forming process, the first insulating film is formed on the surface of the semiconductor substrate in a range outside the conductive layer. In the second insulating film forming process, the second insulating film is formed on the conductive layer. In the first contact hole forming process, the first contact hole is formed in the first insulating film. In the second contact hole forming process, a second contact hole having a width wider than that of the first contact hole is formed in the second insulating film. In the metal layer forming process, a metal layer is formed on the first insulating film, in the first contact hole, on the second insulating film and in the second contact hole. In the metal layer etching process, the metal layer is etched so that a part of the metal layer remains at a corner potion between a side surface of the second contact hole and a bottom surface of the second contact hole and another part of the metal layer remains in the first contact hole. In the first surface electrode forming process, a first surface electrode extending from a position on the first insulating film to a position on the contact plug is formed. In the second surface electrode forming process, a second surface electrode extending from a position on the second insulating film to a position in the second contact hole and covering the part of the metal layer at the corner portion is formed.

The first insulating film forming process and the second insulating film forming process may be performed simultaneously.

In this method, after the formation of the first insulating film, second insulating film, first contact hole, and second contact hole, a metal layer is allowed to develop in the first and second contact holes. Since the first contact hole has a narrow width, the first contact hole is filled with the metal layer without a gap. Since the second contact hole has a wide width, an internal surface of the second contact hole is covered with a metal layer of substantially uniform thickness. Next, the metal layer is etched. Here, etching is carried out so that a part of the metal layer remains in the first contact hole and another part of the metal layer also remains on the corner portion between the side surface and the bottom of the second contact hole. Since the first contact hole is filled with the metal layer without a gap, the metal layer in the first contact hole is etched starting from an opening side of the contact hole. Therefore, a large amount of the metal layer remains in the first contact hole, which forms a contact plug. Meanwhile, the internal surface of the second contact hole has been covered with the metal layer of substantially uniform thickness. Therefore, in the second contact hole, the metal layer is etched along a direction of the substantially uniform thickness. Accordingly, the metal layer in the second contact hole is etched more easily than that in the first contact hole. However, etching agent does not easily reach vicinity of the corner portion between the side surface and the bottom of the second contact hole, resulting in that an etching speed decreases at the corner portion. Accordingly, a part of the metal layer can be allowed to remain on the corner portion of the second contact hole. Thus, a side metal layer is formed. Due to this, the contact plug and side metal layer are configured of a same kind of metal. Thereafter, the first surface electrode and the second surface electrode are formed. The second surface electrode is formed so as to extend from a portion on the upper surface of the second insulating film to a position in the second contact hole (i.e., so as to cover the side metal layer). Forming the second surface electrode so as to cover the side metal layer enables the second surface electrode to have a smooth surface. The formation of the smooth surface of the second surface electrode enables improvement of strength of the second surface electrode. Accordingly, this method enables manufacturing of a semiconductor device in which the second surface electrode is made less liable to be peeled off. Additionally, in this method, the process of forming the metal layer and the process of etching the metal layer for the formation of the contact plug simultaneously allow the formation of the side metal layer. Thus, the side metal layer can be formed without increasing a number of processes. Accordingly, this semiconductor device can be manufactured efficiently.

### BRIEF DESCRIPTION OF DRAWING

FIG. 1 is plan view of a semiconductor device 10.

FIG. 2 shows vertical sections of the semiconductor device 10 taken along line A-A and line B-B, respectively, in FIG. 1.

FIG. 3 is an enlarged sectional view of a barrier metal 28.

FIG. 4 is an explanatory view for a manufacturing process for the semiconductor device 10.

FIG. 5 is an explanatory view for the manufacturing process for the semiconductor device 10.

FIG. 6 is an explanatory view for the manufacturing process for the semiconductor device 10.

FIG. 7 is an explanatory view for the manufacturing process for the semiconductor device 10.

FIG. 8 is an explanatory view for the manufacturing process for the semiconductor device 10.

FIG. 9 is an explanatory view for the manufacturing process for the semiconductor device 10.

FIG. 10 is an explanatory view for the manufacturing process for the semiconductor device 10.

FIG. 11 is an explanatory view for the manufacturing process for the semiconductor device 10.

FIG. 12 is an explanatory view for the manufacturing process for the semiconductor device 10.

FIG. 13 is an explanatory view for the manufacturing process for the semiconductor device 10.

FIG. 14 is an explanatory view for the manufacturing process for the semiconductor device 10.

FIG. 15 is an explanatory view for the manufacturing process for the semiconductor device 10.

FIG. 16 is an explanatory view for the manufacturing process for the semiconductor device 10.

FIG. 17 is a sectional view of a semiconductor device of a comparative example.

FIG. 18 is an explanatory view for the manufacturing process for the semiconductor device 10.

FIG. 19 is an explanatory view for the manufacturing process for the semiconductor device 10.

FIG. 20 is a vertical sectional view of a pad part 14 of a vertical semiconductor device in Embodiment 2.

FIG. 21 is a vertical sectional view of a semiconductor device in Embodiment 3, corresponding to FIG. 2.

FIG. 22 is a vertical sectional view of a semiconductor device in Embodiment 4, corresponding to FIG. 2.

FIG. 23 is a vertical sectional view of a semiconductor device in Embodiment 5, corresponding to FIG. 2.

### DETAILED DESCRIPTION OF EMBODIMENT

### Embodiment 1

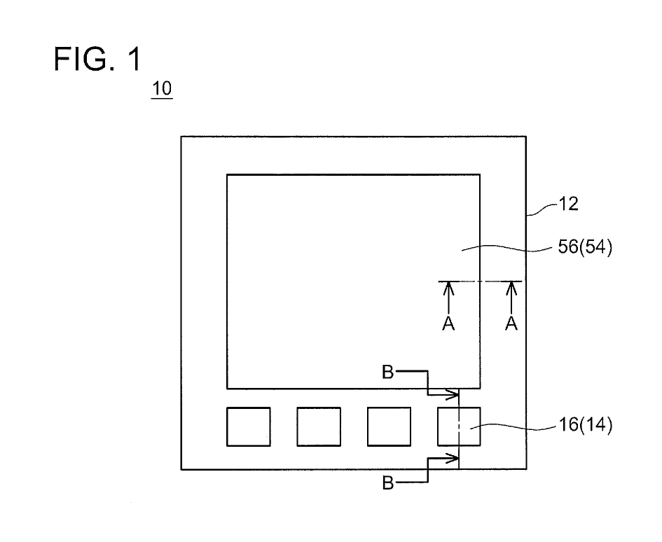

As shown in FIG. 1, a semiconductor device 10 according to Embodiment 1 has a semiconductor substrate 12. The semiconductor substrate 12 is configured of silicon. An emitter electrode 56 and a plurality of bonding pads 16 are provided on an upper surface of the semiconductor substrate 12. Hereinafter, a vicinity of the emitter electrode 56 in the semiconductor device 10 is called a cell part 54. Additionally, a vicinity of each bonding pad 16 in the semiconductor device 10 is called a pad part 14.

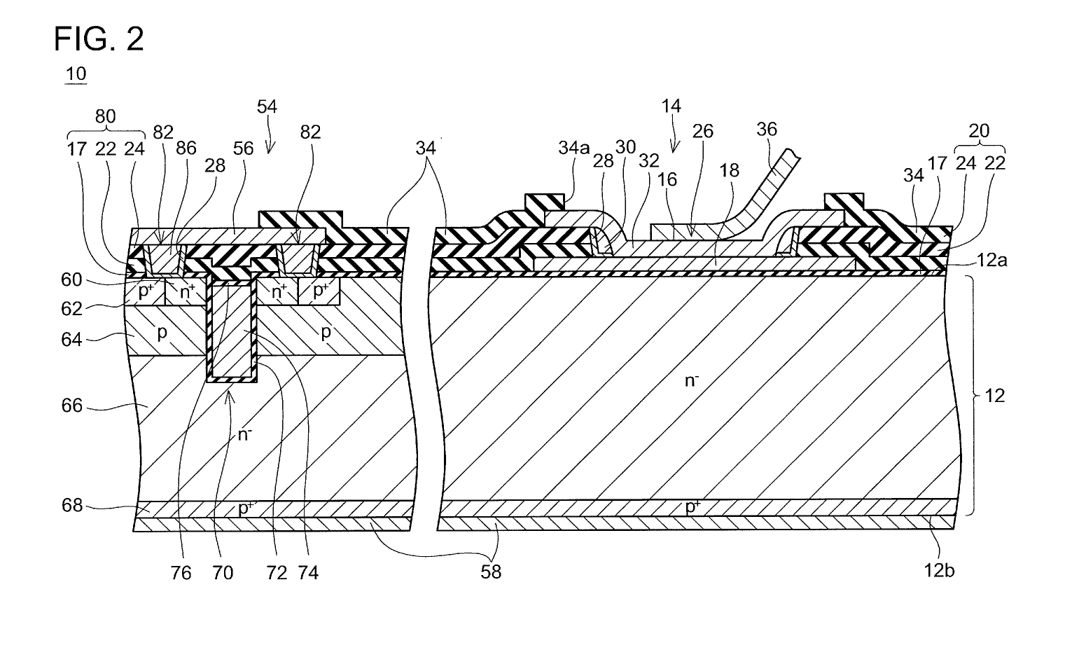

FIG. 2 shows respective vertical sections of the pad part 14 and cell part 54 of the semiconductor device 10. A collector electrode 58 extending from the pad part 14 to the cell part 54 is provided on a lower surface 12b of the semiconductor substrate 12.

A surface oxide film 17 is provided on the upper surface 12a of the semiconductor substrate 12 in the pad part 14. The surface oxide film 17 is configured of SiO₂. The surface oxide film 17 covers an entire area of the upper surface 12a of the semiconductor substrate 12 in the pad part 14. The surface oxide film 17 is obtained by oxidizing the semiconductor substrate 12.

A gate wiring 18 is provided on the surface oxide film 17. The gate wiring 18 is configured of polysilicon.

An insulating film 20 configured of SiO₂ is formed on the surface oxide film 17 and the gate wiring 18. The insulating film 20 covers an upper surface of the gate wiring 18 and the upper surface of the surface oxide film 17 on which the gate wiring 18 is not formed. The insulating film 20 has an NSG film 22 and a BPSG film 24. The NSG film 22 is configured of NSG (Non-doped Silicon Glass). That is, the NSG film 22 is configured of SiO₂ in which boron and phosphorus are not doped. The NSG film 22 is disposed on the surface oxide film 17 and gate wiring 18. The BPSG film 24 is configured of BPSG (Boron Phosphorus Silicon Glass). That is, the BPSG film 24 is configured of SiO₂ in which boron and phosphorus are doped. The BPSG film 24 is formed on the NSG film 22. In a place where the gate wiring 18 is not provided, the insulating film 20 is provided on the surface oxide film 17.

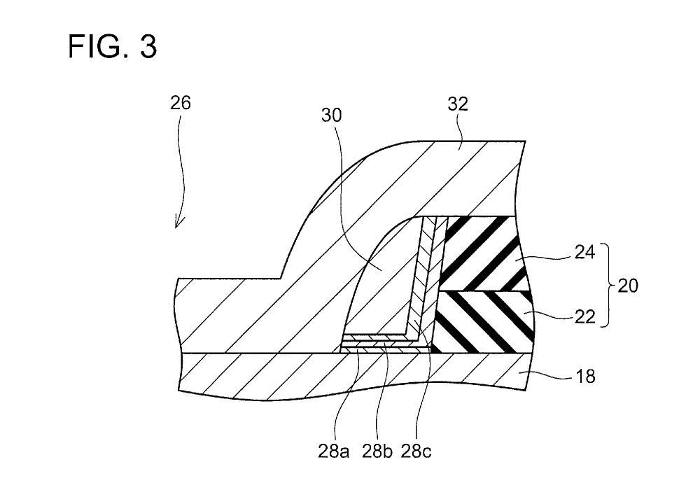

A contact hole 26 is provided in the insulating film 20. The contact hole 26 is provided in the insulating film 20 located on the gate wiring 18. The contact hole 26 penetrates the insulating film 20 from its upper surface to lower surface, formed within the range of the gate wiring 18. A bottom of the contact hole 26 is configured of the gate wiring 18. The contact hole 26 has a width sufficient for wire bonding in its inside. The width of the contact hole 26 can be equal to 150 μm or wider and is about 800 μm in the present embodiment. Side faces of the contact hole 26 (i.e., side surfaces of the insulating film 20) and its bottom (i.e., the upper surface of the gate wiring 18) in the vicinity of these side faces are covered with a barrier metal 28. As shown in FIG. 3, the barrier metal 28 has a TiSi layer 28a, Ti layer 28b, and Tin layer 28c. The TiSi layer 28a is provided on the upper surface of the gate wiring 18. The TiSi layer 28a is in contact with the gate wiring 18 at low resistance. The Ti layer 28b covers an upper surface of the TiSi layer 28a and the side surfaces of the insulating film 20. The TiN layer 28c covers a surface of the Ti layer 28b.

A corner portion between the side surface of the contact hole 26 (i.e., the side surface of the insulating film 20) and the bottom of the contact hole 26 is covered with a side metal layer 30. More specifically, the side metal layer 30 covers almost an entire area of the side surface of the contact hole 26 and the bottom of the contact hole 26 in the vicinity of the corner. The side metal layer 30 covers the corner portion of the contact hole 26 from above the barrier metal 28. That is, the barrier metal 28 is interposed between the side metal layer 30 and the surface of the contact hole 26 (i.e., the side surface and the bottom of the contact hole 26). On a middle part of the bottom of the contact hole 26, the side metal layer 30 is not arranged. In the present embodiment, the side metal layer 30 is configured of tungsten. A thickness of the side metal layer 30 (i.e., the thickness of the side metal layer 30 when measured in a direction perpendicular to the side surfaces of the contact hole 26) increases as the side metal layer 30 extends from its upper side to its lower side. Accordingly, a surface of the side metal layer 30 inclines in a tapered manner.

A surface electrode 32 is provided so as to extend from a position on an upper surface of the insulating film 20 to a position in the contact hole 26. In the present embodiment, the surface electrode 32 is configured of AlSi. The surface electrode 32 covers the side metal layer 30. The surface electrode 32 covers the bottom of the contact hole 26. That is, the surface electrode 32 is in contact with the gate wiring 18 on the bottom of the contact hole 26. Additionally, the surface electrode 32 covers an upper surface of the BPSG film 24.

As shown in FIG. 2, a polyimide film 34 is provided on the insulating film 20, in a range where the surface electrode 32 is not provided. The polyimide film 34 is an insulating film. An opening 34a is provided in the polyimide film 34. The surface electrode 32 is exposed in the opening 34a. The polyimide film 34 also covers ends of the surface electrode 32. A surface of the surface electrode 32 located in the opening 34a serves as a bonding pad 16. The bonding pad 16 is provided in the contact hole 26. A wire 36 configured of Al is bonded to one end of the bonding pad 16. The other end of the wire 36 is connected to an electrode (not shown).

In the cell part 54, an IGBT is formed. The IGBT has a structure described below. An emitter region 60, a body contact region 62, a body region 64, a drift region 66, and a collector region 68 are provided in the semiconductor substrate 12 in the cell part 54. The emitter region 60 is of n-type and provided in a position facing the upper surface 12a of the semiconductor substrate 12. The body contact region 62 is of p⁺-type and provided in a position facing the upper surface 12a of the semiconductor substrate 12. The body region 64 is of p⁻-type and provided under the emitter region 60 and body contact region 62. A P-type impurity concentration in the body region 64 is lower than a p-type impurity concentration in the body contact region 62. The drift region 66 is of n-type and provided under the body region 64. The drift region 66 is also provided in the semiconductor substrate 12 of the pad part 14. The collector region 68 is of p-type and provided under the drift region 66. The collector region 68 is also provided in the semiconductor substrate 12 of the pad part 14. The collector region 68 is provided in a position facing the lower surface 12b of the semiconductor substrate 12. The collector region 68 is connected to the collector electrode 58.

Trenches 70 (only one trench 70 is shown in FIG. 2) are formed on the upper surface 12a of the semiconductor substrate 12 in the cell part 54. The trench 70 penetrates the emitter region 60 and body region 64 so as to reach the drift region 66. An internal surface of the trench 70 is covered with a gate insulating film 72. A gate electrode 74 is provided in the trench 70. The gate electrode 74 is insulated from the semiconductor substrate 12 by the gate insulating film 72. The gate electrode 74 faces the emitter region 60, body region 64, and drift region 66 via the gate insulating film 72. The gate electrode 74 is connected to the gate wiring 18, described above, in a place not shown. The gate electrode 74 is electrically connected to the surface electrode 32 (that is, the wire 36) via the gate wiring 18. An upper surface of the gate electrode 74 is covered with a cap insulating film 76.

The upper surface 12a of the semiconductor substrate 12 in the cell part 54 is covered with an insulating film 80 configured of SiO₂. The insulating film 80 is configured of the aforementioned surface oxide film 17, NSG film 22, and BPSG film 24. That is, in the cell part 54, the surface oxide film 17, NSG film 22, and BPSG film 24 are arranged in layers on the upper surface 12a of the semiconductor substrate 12, and these collectively form the insulating film 80.

A plurality of contact holes 82 is provided in the insulating film 80. Each contact hole 82 extends through the insulating film 80, from its upper surface to its lower surface. A width of each contact hole 82 is narrower than the width of the contact hole 26. The width of the contact hole 82 can be equal to or less than 1 μm and is about 0.8 μm in the present embodiment. The bottom of each contact hole 82 is configured of the upper surface 12a of the semiconductor substrate 12. The emitter region 60 and body contact region 62 face the bottom of each contact hole 82. An internal surface of the contact hole 82 (i.e., the upper surface 12a of the semiconductor substrate 12, forming the bottom of each contact hole 82, and side faces of the insulating film 80) is covered with the barrier metal 28 described above. The barrier metal 28 in the cell part 54 has a laminate structure of a TiSi layer, Ti layer, and TiN layer, as with the barrier metal 28 in the pad part 14 described above.

A contact plug 86 is disposed in each contact hole 82. The contact plug 86 fills the corresponding contact hole 82. In the present embodiment, the contact plug 86 is configured of tungsten. The contact plug 86 covers a surface of the barrier metal 28 in the contact hole 82.

An emitter electrode 56 is provided on surfaces of the insulating film 80 and contact plugs 86. The emitter electrode 56 extends from a position on the upper surface of the insulating film 80 to a position on the upper surfaces of the contact plugs 86. In the present embodiment, the emitter electrode 56 is configured of AlSi. The emitter electrode 56 is connected to the emitter region 60 and body contact region 62 via the contact plugs 86 and barrier metals 28.

On the insulating film 80, in a range where the emitter electrode 56 is not formed, the aforementioned polyimide film 34 is provided. The polyimide film 34 also covers an end of the emitter electrode 56. Although not shown, the emitter electrode 56 in a range where the emitter electrode 56 is not covered with the polyimide film 34, is soldered to an external electrode.

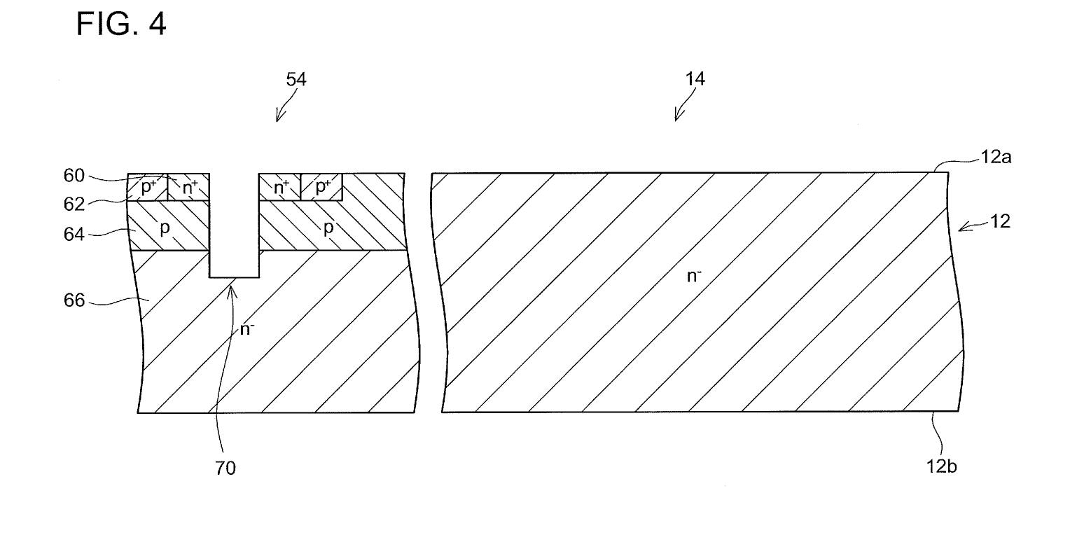

Next, a manufacturing method for a semiconductor device 10 will be described. The semiconductor device 10 is manufactured from an n-type semiconductor substrate 12 having a same n-type impurity concentration as that in a drift region 66. First, as shown in FIG. 4, an emitter region 60, a body contact region 62, and a body region 64 are formed in the semiconductor substrate 12 by ion implantation. Next, a trench 70 is formed by anisotropic etching.

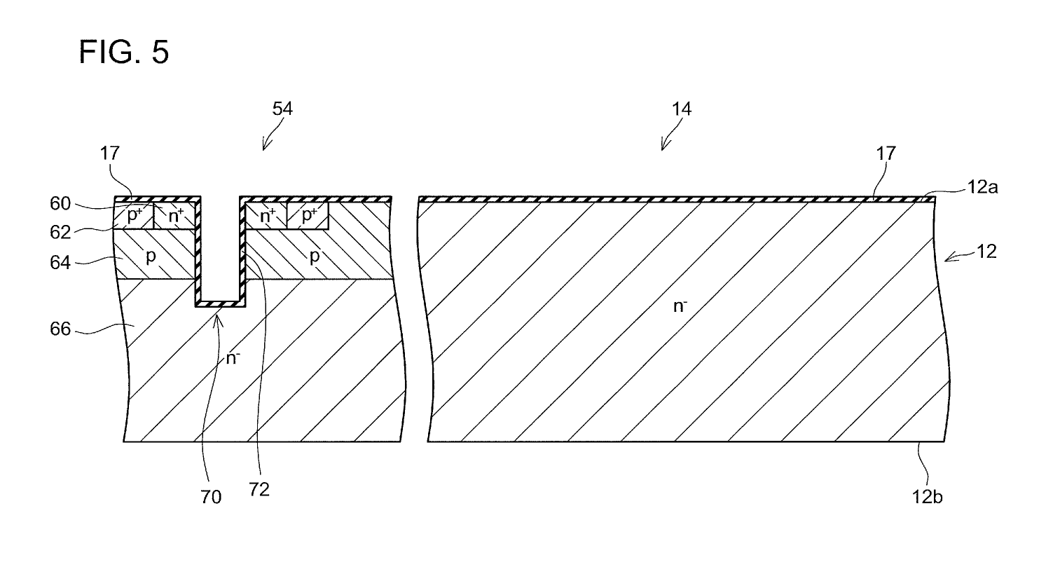

Next, as shown in FIG. 5, a surface of the semiconductor substrate 12 is oxidized, thereby forming a gate insulation film 72 and a surface oxide film 17.

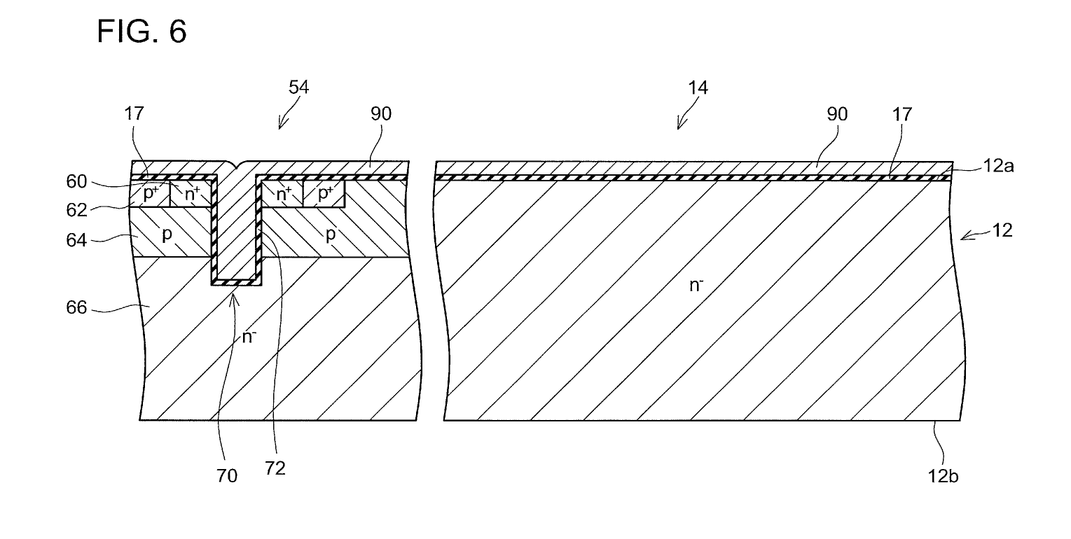

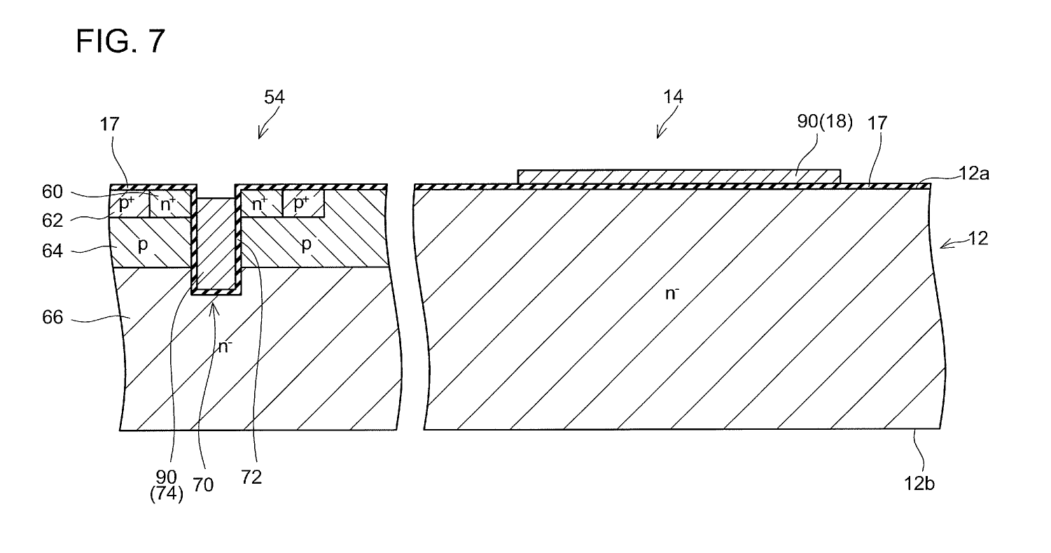

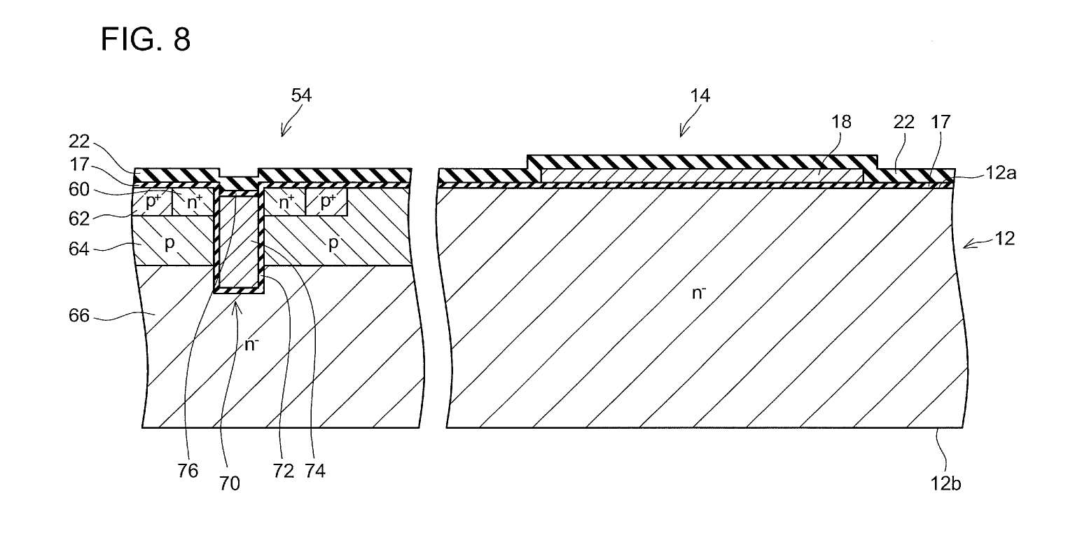

Next, as shown in FIG. 6, a polysilicon layer 90 is allowed to develop on the semiconductor substrate 12. Next, the polysilicon layer 90 is selectively etched. Here, as shown in FIG. 7, a part of the polysilicon layer 90 is allowed to remain in the trench 70. The part of the polysilicon layer 90 remaining in the trench 70 serves as a gate electrode 74. Additionally, as shown in FIG. 7, another part of the polysilicon layer 90 is allowed to remain on the surface oxide film 17 in a pad part 14. The part of the polysilicon layer 90 remaining on the surface oxide film 17 serves as a gate wiring 18. Next, as shown in FIG. 8, a cap insulating film 76 is formed on an upper surface of the gate electrode 74.

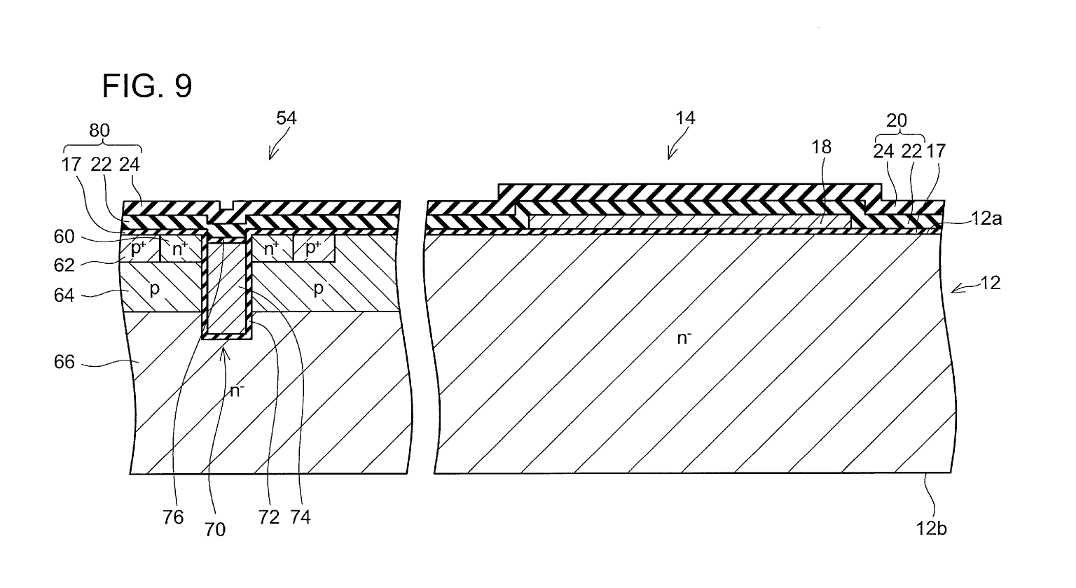

Subsequently, as shown in FIG. 8, an NSG film 22 is allowed to develop on the semiconductor substrate 12 by CVD. The surface oxide film 17 and gate wiring 18 are covered with the NSG film 22. Subsequently, as shown in FIG. 9, a BPSG film 24 is allowed to develop on the NSG film 22 by CVD. Formation of the BPSG film 24 completes an insulating film 20 in the pad part 14 and an insulating film 80 in the cell part 54. In the formation of the BPSG film 24, the NSG film 22 prevents boron and phosphorus in the BPSG film 24 from diffusing in the semiconductor substrate 12. Thus, the forming of the NSG film 22 prior to the forming of the BPSG film 24 can prevent the diffusion of boron and phosphorus from the BPSG film 24 into the semiconductor substrate 12.

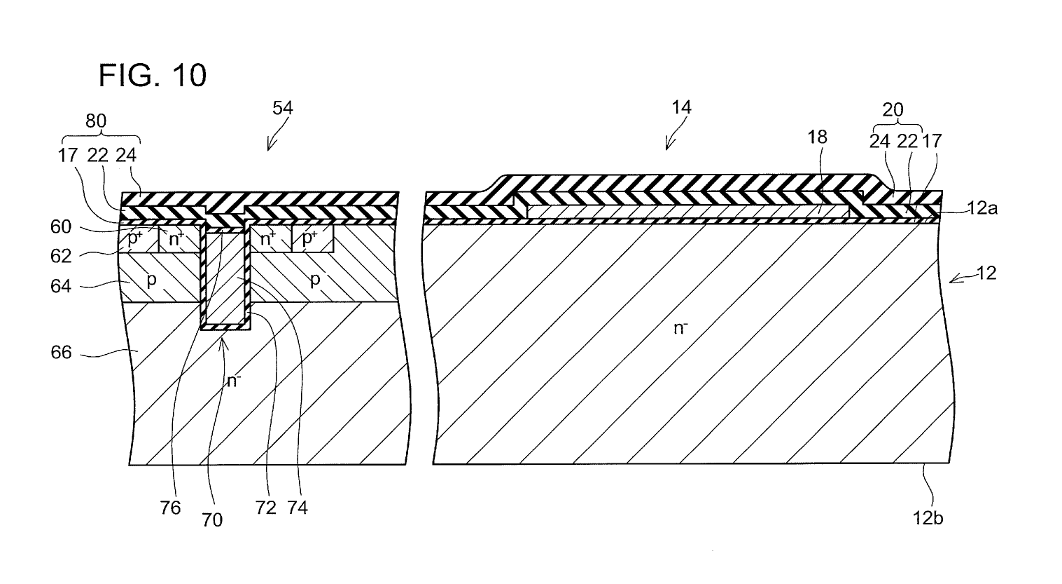

Next, the semiconductor substrate 12 is heat treated. During the heat treatment, the BPSG film 24 flows, so that a surface of the BPSG film 24 is flattened. Therefore, as shown in FIG. 10, the surface of the BPSG film 24 after the heat treatment is flatter than that before the heat treatment.

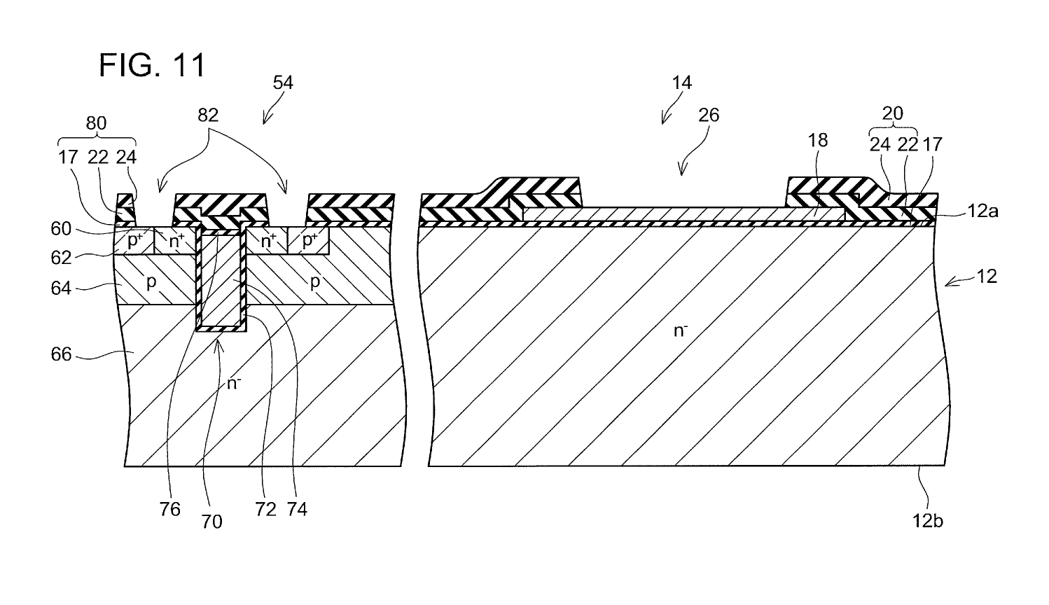

Next, as shown in FIG. 11, the insulating films 20, 80, are selectively etched to form contact holes 26, 82.

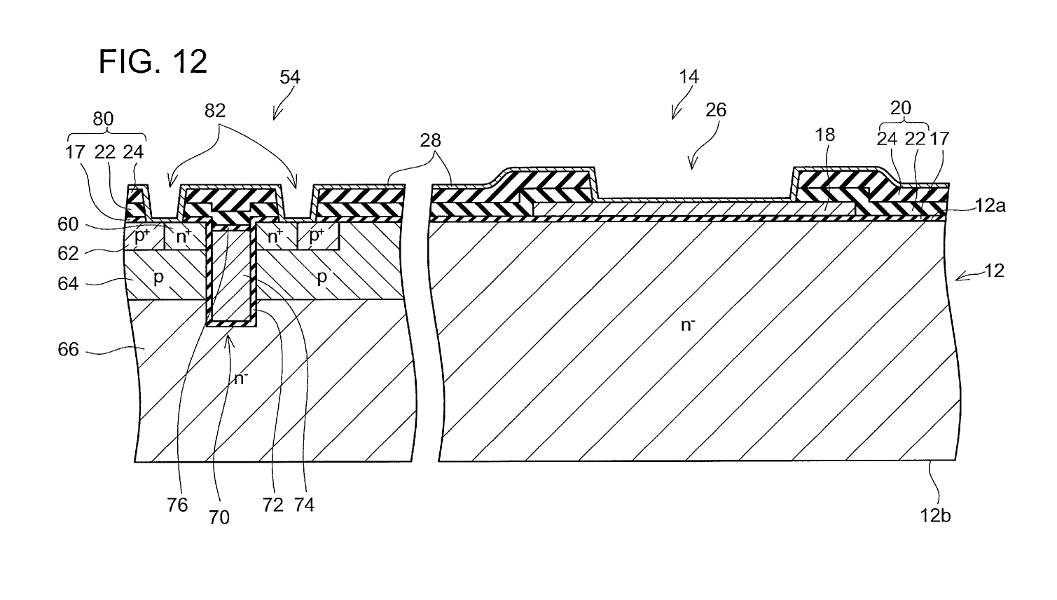

Subsequently, as shown in FIG. 12, a barrier metal 28 is formed on the surface of the semiconductor substrate 12. The barrier metal 28 is formed so as to cover respective internal surfaces of the contact holes 26, 82 and the upper surface of the BPSG film 24. More specifically, the barrier metal 28 is formed as described below. First, a Ti layer (i.e., the Ti layer 28b in FIG. 3) is formed on the surface of the semiconductor substrate 12. Meanwhile, on a bottom of each contact hole 26, Ti of the Ti layer and silicon of the gate wiring 18 become alloyed, thereby forming a TiSi layer (i.e., the TiSi layer 28a in FIG. 3). The TiSi layer 28a is connected to the gate wiring 18 at low resistance. Additionally, on a bottom of each contact hole 82, Ti of the Ti layer and silicon of the semiconductor substrate 12 are alloyed, thereby forming a TiSi layer. This TiSi layer is connected to the semiconductor substrate 12 at low resistance. Next, a TiN layer (i.e., the TiN layer 28c in FIG. 3) is formed on the Ti layer. Thus, the barrier metal 28 shown in FIG. 12 is obtained.

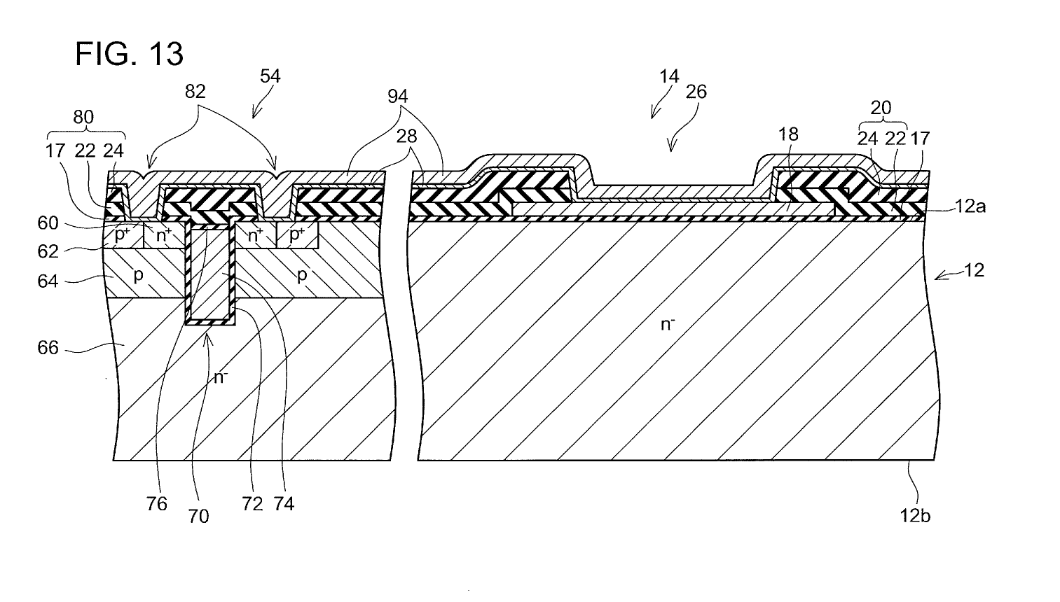

Next, as shown in FIG. 13, a tungsten layer 94 is allowed to develop on the surface of the semiconductor substrate 12. The tungsten layer 94 develops on the barrier metal 28 that is located on the respective internal surfaces of the contact holes 26, 82 and on the upper surface of the BPSG film 24. Here, the tungsten layer 94 is formed so as to have a thickness (i.e., thickness equal to or greater than 0.3 μm) equal to or greater than a half of a width of each contact hole 82 (approximately 0.6 μm in the present embodiment). In the present embodiment, the thickness of the tungsten layer 94 is approximately 0.4 μm. By virtue of this, the tungsten layer 94 develops to fill each contact hole 82 without any gap. Additionally, the width (approximately 800 μm) of the contact hole 26 is far greater than that (approximately 0.4 μm) of the tungsten layer 94. Therefore, in the contact hole 26, the tungsten layer 94 develops to be formed along the internal surface of the contact hole 26. That is, the tungsten layer 94 develops to have a substantially uniform thickness along the internal surface of the contact hole 26. When the tungsten layer 94 is formed, the barrier metal 28 (particularly, the TiN layer) prevents tungsten forming the tungsten layer 94 from diffusing in the semiconductor substrate 12. Thus, formation of a defect in the contact part of the semiconductor substrate 12 is prevented. Additionally, the barrier metal 28 prevents the tungsten from diffusing into the gate wiring 18 from the tungsten layer 94.

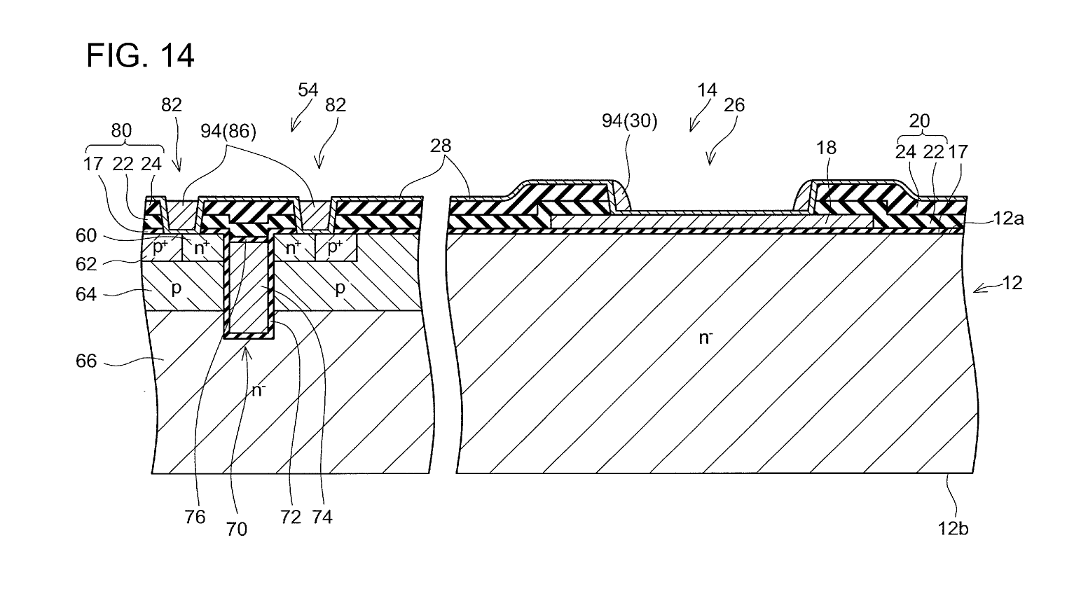

Next, as shown in FIG. 14, the tungsten layer 94 is etched, so that the tungsten layer 94 located on tops of the insulating films 20, 80 are removed. Thus, the barrier metal 28 on the insulating films 20, 80 is exposed. Additionally, a part of the tungsten layer 94 is allowed to remain in the contact holes 82. More specifically, etching is carried out such that an upper surface of the part of the tungsten layer 94 remaining in each contact hole 82 is set substantially at a same level as the upper surface of the insulating film 80. The part of the tungsten layer 94 remaining in the contact hole 82 serves as a contact plug 86. Additionally, the tungsten layer 94 in the contact hole 26 is also etched. The thickness of the tungsten layer 94 on the bottom of the contact hole 26 is substantially equal to the thickness of the tungsten layer 94 located on the tops of the insulating films 20, 80. Therefore, the tungsten layer 94 on the bottom of the contact hole 26 is removed. Consequently, the barrier metal 28 is exposed on the bottom of the contact hole 26. Meanwhile, etching agent does not easily reach vicinity of the corner portion between the bottom and side surfaces of the contact hole 26, resulting in that an etching speed decreases near the corner portion. As a result of this, a part of the tungsten layer 94 remains such that the part of the layer 94 covers the corner portion of the contact hole 26 (specifically, the side surfaces and the bottom near the corner portion). The part of the tungsten layer 94 remaining in the vicinity of the corner portion of the contact hole 26 serves as a side metal layer 30. In the present embodiment, the side metal layer 30 remains such that the layer 30 covers almost entire areas of the side surfaces of the contact hole 26. Alternatively, in another embodiment, a side metal layer 30 may be formed only in an area in vicinity of the corner portion among the side surfaces of the contact hole 26. By forming the side metal layer 30 in this way, a thickness of the side metal layer 30 (i.e., a width of the side metal layer 30 in a direction perpendicular to the side surfaces of the contact hole 26) increases towards the lower side from the upper side. As a result of this, a surface of the side metal layer 30 is formed such that this surface inclines in a tapering manner. As a result of this, a level difference in outer peripheral edges of the contact hole 26 is smoothed by the side metal layer 30.

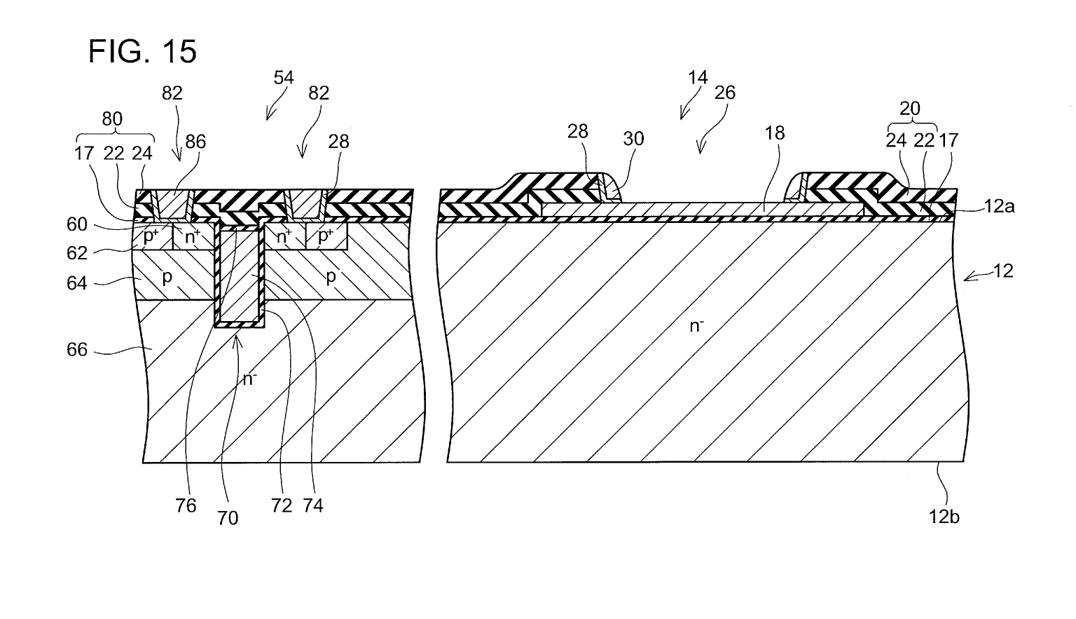

Next, as shown in FIG. 15, the barrier metal 28 is etched to remove the barrier metal 28 on the insulating films 20, 80. Thus, the upper surface of the BPSG film 24 is exposed. Since the barrier metal 28 in each contact hole 82 is covered with the respective contact plug 86, the barrier metal 28 in each contact hole 28 is not etched. Consequently, the barrier metal 28 remains in the contact holes 82. The barrier metal 28 under the side metal layer 30 in the contact hole 26 is not etched, either. That is, the barrier metal 28 remains between the side metal layer 30 and gate wiring 18 and between the side metal layer 30 and the insulating film 20. The barrier metal 28 in a range where the barrier metal 28 is not covered with the side metal layer 30 in the contact hole 26 (i.e., the barrier metal 28 on the bottom of the contact hole 26) is removed. Consequently, the gate wiring 18 is exposed on the bottom of the contact hole 26.

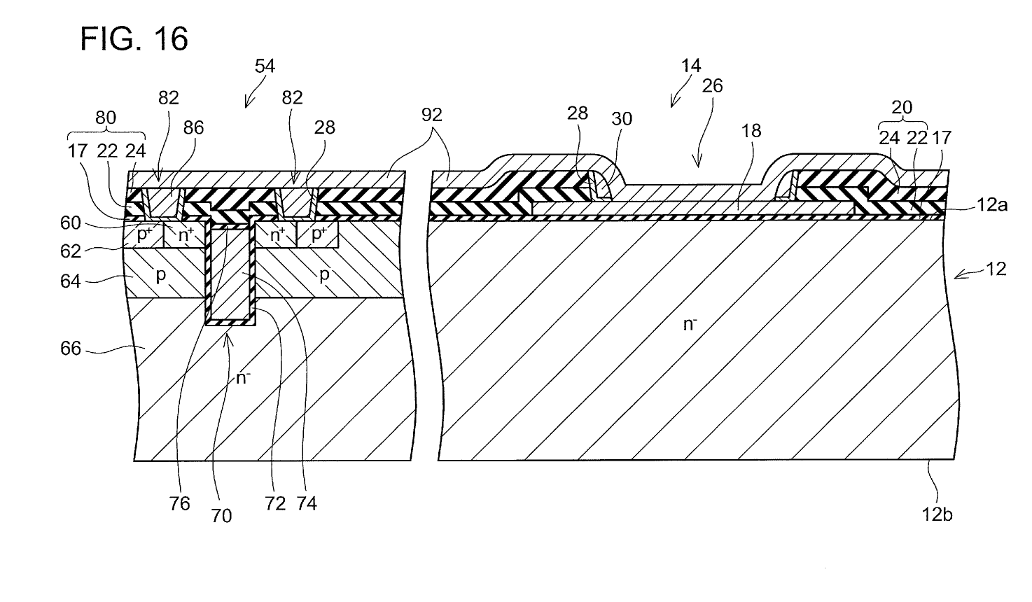

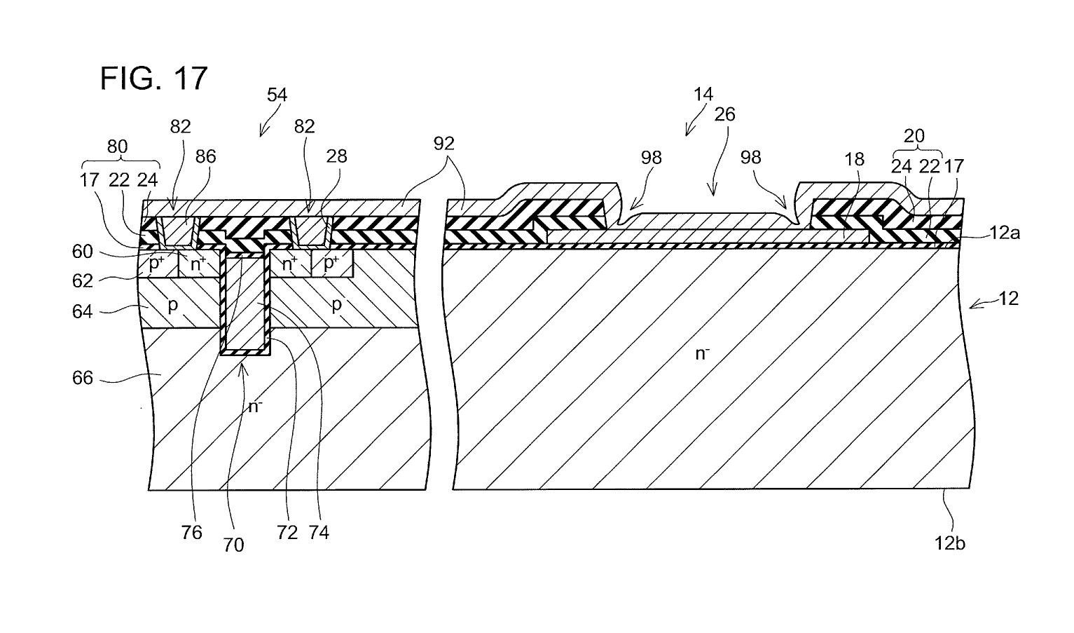

Next, as shown in FIG. 16, an AlSi layer 92 is allowed to develop on the surface of the semiconductor substrate 12. In the present embodiment, the AlSi layer 92 is allowed to develop at a low temperature (e.g., a temperature of 200° C. or below). Developing the AlSi layer 92 at a low temperature can suppress precipitation of nodules of Si in the AlSi layer 92, thus enabling the formation of the AlSi layer 92 of high strength. Additionally, developing the AlSi layer 92 on a surface that has recesses and projections may result in formation of a deep groove in a surface of the AlSi layer 92. Particularly, where an AlSi layer 92 is allowed to develop at a low temperature, a groove is liable to be formed in the surface of the AlSi layer 92. In the present embodiment, the surface of the cell part 54 (i.e., the surface comprising of the upper surface of the insulating film 80 and the upper surfaces of the contact plugs 86) is substantially flat Accordingly, it is possible to form on the cell part 54 an AlSi layer 92 having a flat surface. Additionally, in the pad part 14, a level difference is present between the bottom of the contact hole 26 and the upper surface of the insulating film 20. However, this level difference is smoothed by the side metal layer 30. Accordingly, as shown in FIG. 16, in the pad part 14 also, the surface of the AlSi layer 92 is smoothed with no groove in the AlSi layer 92. FIG. 17 shows a case where the AlSi layer 92 is formed in a state where the side metal layer 30 is not present. If the side metal layer 30 is not present, the AlSi layer 92 directly develops on the corner portion between the side surfaces and bottom of the contact hole 26. If the AlSi layer 92 develops in such a manner, groove 98 are formed in the surface of the AlSi layer 92 in vicinity of the corner portion. In contrast, the method according to the present embodiment is able to prevent formation of the groove 98, as shown in FIG. 16. Depending on conditions, even with the method according to the present embodiment, the groove 98 may be formed. However, in this case, a depth of the groove 98 can be made shallower than that in FIG. 17. If deep groove 98 are formed as in FIG. 17, the strength of the AlSi layer 92 is decreased. The deep groove 98 as in FIG. 17 are likely to become a starting point of a crack, resulting in a decrease in durability of the AlSi layer 92. Compared to this, the method according to the present embodiment is able to form the AlSi layer 92 of high strength and durability.

The BPSG film 24 is exposed before the formation of the AlSi layer 92. Therefore, the AlSi layer 92 is in direct contact with the BPSG film 24. Therefore, the AlSi layer 92 is adhered with high strength to the BPSG film 24. This makes the AlSi layer 92 less liable to be peeled off. That is, if the barrier metal 28 is interposed between the BPSG film 24 and AlSi layer 92, the barrier metal 28 is liable to be peeled off from the BPSG film 24. Therefore, the AlSi layer 92 may easily be peeled off from the BPSG film 24 together with the barrier metal 28. In contrast, in the present embodiment, the AlSi layer 92 is in direct contact with the BPSG film 24, thus suppressing the AlSi layer 92 from being peeled off from the BPSG film 24.

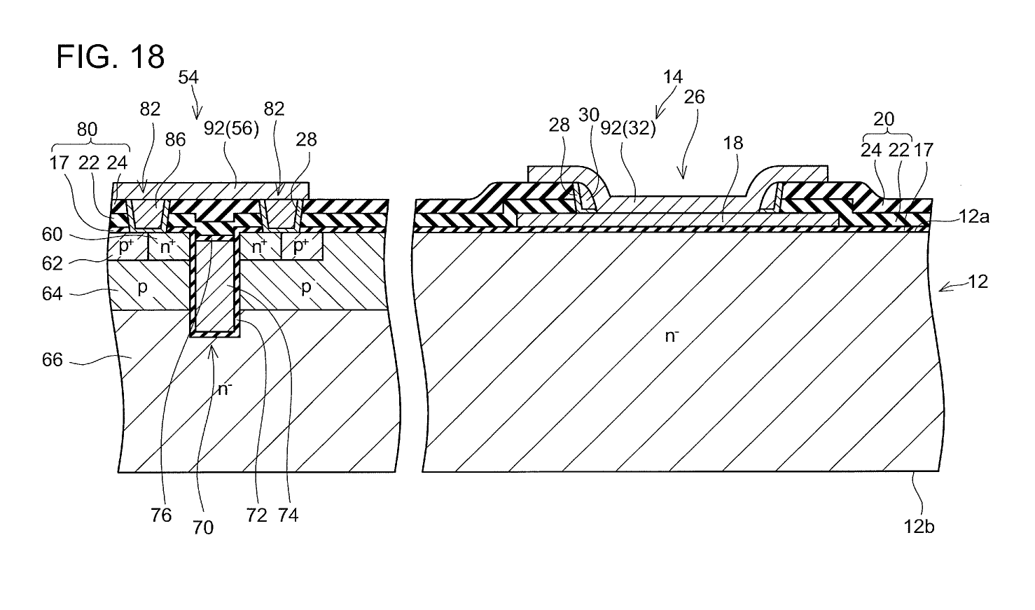

Next, as shown in FIG. 18, the AlSi layer 92 is selectively etched, thereby patterning the AlSi layer 92. Consequently, a surface electrode 32 is formed by the AlSi layer 92 extending from a position on the upper surface of the insulating film 20 to a position in the contact hole 26. Additionally, an emitter electrode 56 is formed by the AlSi layer 92 extending from a position on the surfaces of the contact plugs 86 to a position on the upper surface of the insulating film 80.

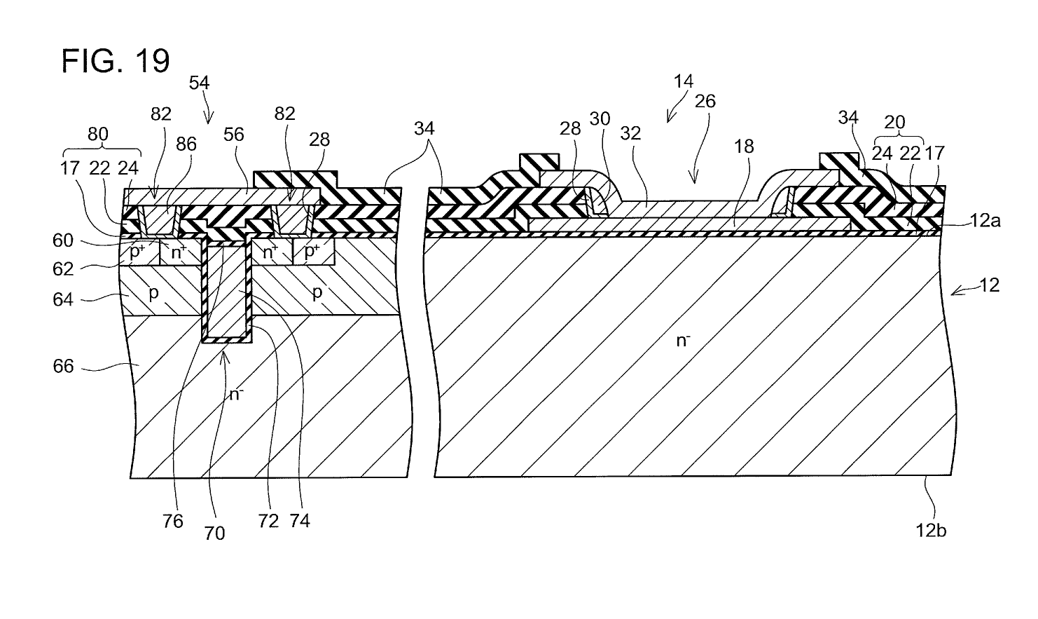

Next, as shown in FIG. 19, a polyimide film 34 is formed on the surface of the BPSG film 24. The polyimide film 34 is formed so as to cover ends of the surface electrode 32. A portion of the surface electrode 32, which is not covered with the polyimide film 34, serves as a bonding pad 16. Additionally, the polyimide film 34 is formed so as to cover ends of the emitter electrode 56

Subsequently, the lower surface 12b side of the semiconductor device 10 is processed to form a collector region 68 and a collector electrode 58. Thus, the semiconductor device 10 shown in FIGS. 1, 2 is completed.

When mounting the semiconductor device 10, the collector electrode 58 is soldered to an electrode (not shown). Additionally, the emitter electrode 56 is soldered to an electrode (not shown). Additionally, one end of the wire 36 is connected to the bonding pad 16. The other end of the wire 36 is connected to an electrode (not shown). When the wire 36 is bonded to the bonding pad 16, the surface electrode 32 is pulled upwards strongly. However, as described above, in the semiconductor device 10, the bonding pad 16 is formed in the contact hole 26. By virtue of this, the surface electrode 32 is connected to the gate wiring 18 on an entire underside of the bonding pad 16. That is, no insulating film is present between the surface electrode 32 and the gate wiring 18 on the underside of the bonding pad 16. By virtue of this, the surface electrode 32 on the underside of the bonding pad 16 is highly strongly connected to the gate wiring 18. Thus, peeling off of the surface electrode 32 is prevented. Accordingly, occurrence of failure during the mounting of the semiconductor device 10 can be prevented. Additionally, as described above, in the semiconductor device 10, the surface electrode 32 has a high strength. This also prevents the peeling off of the surface electrode 32 during wire boding.

Additionally, in Embodiment 1, the surface of the BPSG film 24 is smoothed. Accordingly, the emitter electrode 56 can be formed to be flat on the BPSG film 24. If recesses and projections are formed on a surface of the emitter electrode 56, the emitter electrode 56 is liable to crack due to repeated application of heat to the emitter electrode 56 during the use of the semiconductor device 10. If a crack reaches the semiconductor substrate 12, characteristics of the semiconductor device 10 will degrade. In contrast, the flat surface of the emitter electrode 56 as in Embodiment 1 prevents a crack from occurring and also extending toward the semiconductor substrate 12. Accordingly, the characteristics of the semiconductor device 10 in Embodiment 1 are unlikely to degrade.

Next, correspondence relationships between Embodiments and each of elements in claims will be described. The insulating film 80 in Embodiments is an example of a first insulating film in claims. Each contact hole 82 in Embodiments is an example of a first contact hole in claims. Each contact plug 86 in Embodiments is an example of a contact plug in claims. The emitter electrode 56 in Embodiments is an example of a first surface electrode in claims. The gate wiring 18 in Embodiments is an example of a conductive layer in claims. The insulating film 20 in Embodiments is an example of a second insulating film in claims. The contact hole 26 in the Embodiments is an example of a second contact hole in claims. The side metal layer 30 in Embodiments is an example of a side metal layer in claims. The surface electrode 32 in the Embodiments is an example of a second surface electrode in claims. The surface oxide film 17 in Embodiments is an example of a third insulating film in claims.

### Embodiment 2

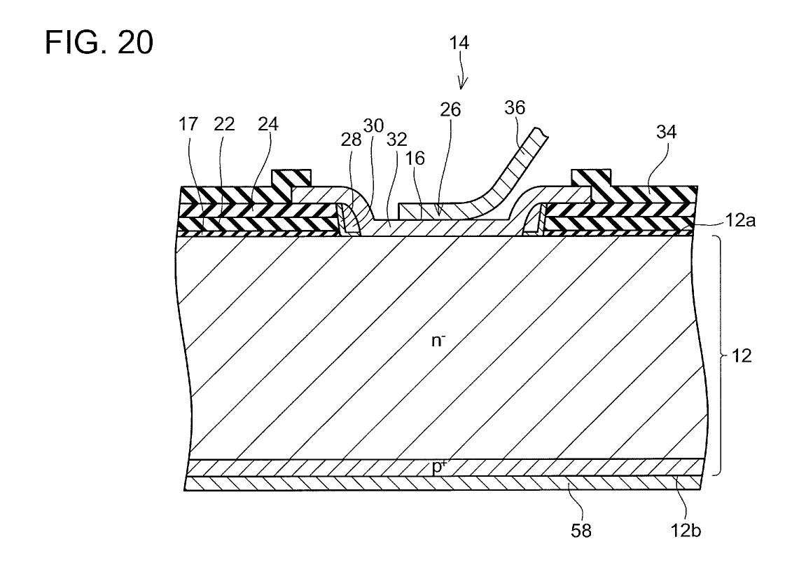

In Embodiment 1 described above, the surface electrode 32 comprising the bonding pad 16 is connected to the gate wiring 18. However, as shown in FIG. 20, a surface electrode 32 may be connected to a semiconductor substrate 12. That is, the conductive layer in claims may be a gate wiring or a semiconductor layer in the semiconductor substrate 12 (more specifically, a semiconductor layer exposed on a surface of the semiconductor substrate 12). Alternatively, the conductive layer may be a wire other than the gate wiring.

### Embodiment 3

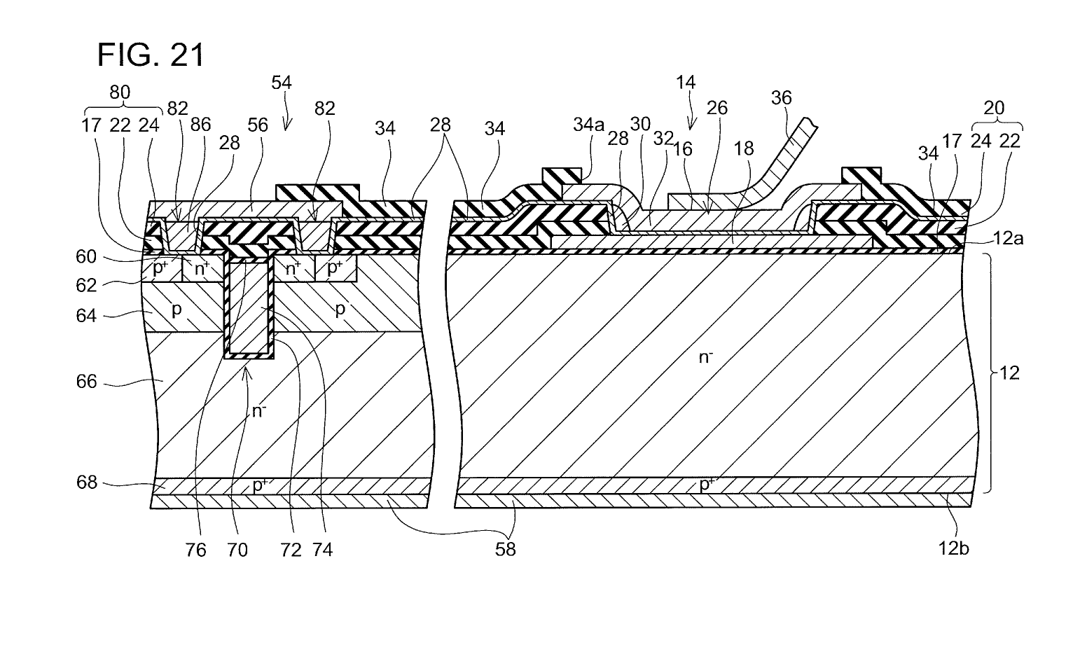

In Embodiment 1 described above, the barrier metal 28 is not formed on the upper surface of the BPSG film 24. By virtue of this, strength of connection between the BPSG film 24 and the electrodes 32, 56 is improved. However, since the BPSG film 24 is formed outside of the bonding pad 16, peeling off of the electrodes 32, 56 on the BPSG film 24 is less likely to result in a problem. Accordingly, as shown in FIG. 21, a barrier metal 28 may be formed on a BPSG film 24.

### Embodiment 4

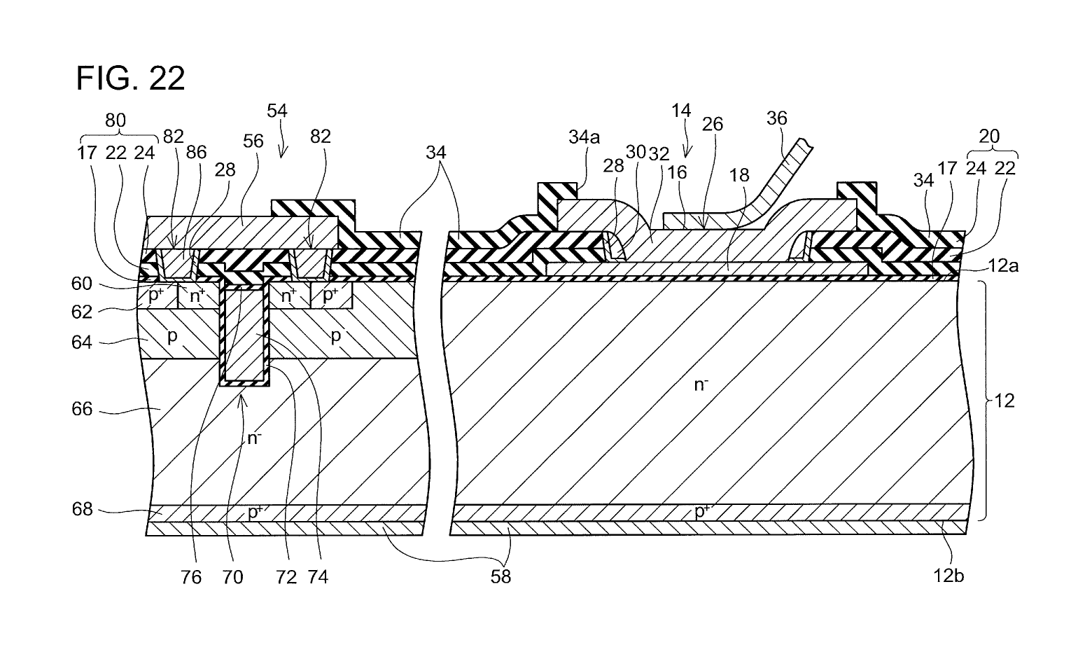

In Embodiment 1 described above, the bonding pad 16 is formed in the contact hole 26. However, as shown in FIG. 22, a bonding pad 16 may be formed in an upper part of a contact hole 26 (i.e., higher than an upper surface of an insulating film 20).

### Embodiment 5

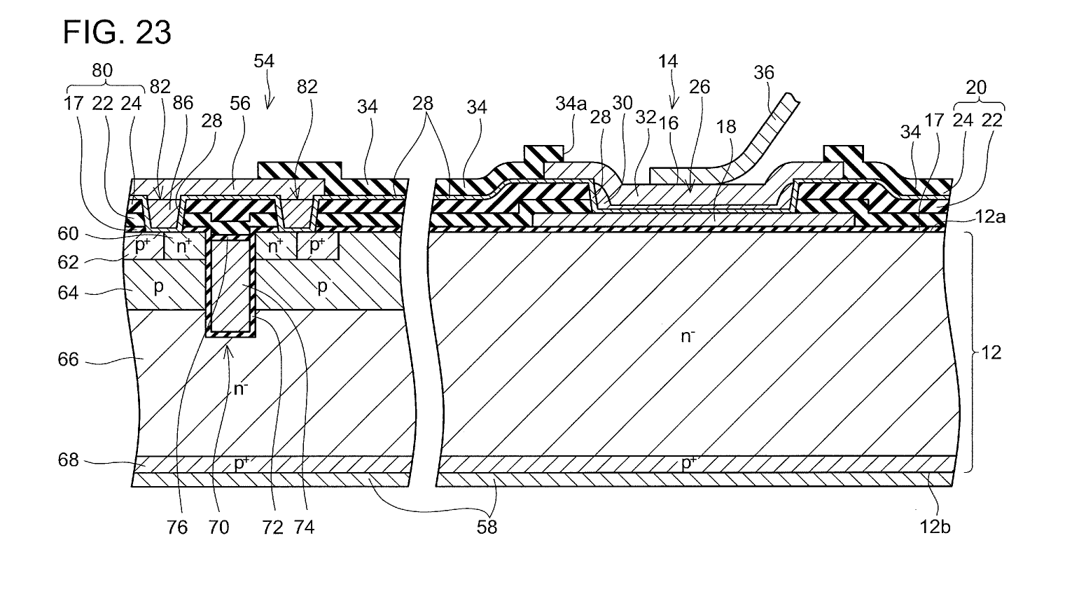

In Embodiments described above, the side metal layer 30 covers the bottom of the contact hole 26 only in the vicinity of the side surfaces of the contact hole 26. However, as shown in FIG. 23, an entire area of a bottom of the contact hole 26 may be covered with a thin side metal layer 30.

In Embodiments described above, as the barrier metal, the laminate structure of the TiSi layer, Ti layer, and TiN layer is employed. However, a barrier metal may be configured of a laminate structure of a TiSi layer and TiN layer. Additionally, the barrier metal contains a metal layer (e.g., Tin, TaN, or the like) that prevents elements of the contact plug on the barrier metal from diffusing under the barrier metal. Additionally, it is preferable for a barrier metal to contain a metal layer (e.g., TiSi, CoSi, NiSi) that is in contact at low resistance with a layer under this barrier metal.

Additionally, in Embodiments described above, tungsten is used as a contact plug. However, various metals that are able to fill the contact holes 82 can be used as a material for a contact plug. For example, Cu or the like can be employed as a material of the contact plug.

Additionally, in Embodiment described above, AlSi is used as the material for the surface electrode 32. However, various conductive materials that allow wire bonding can be employed as a material for the surface electrode. For example, W, Cu or the like can be employed as a material of the surface electrode.

Additionally, a contact plug is a main material of metal with which a contact hole is filled. In a case where a plurality of metal layers is provided in the contact hole, a metal layer occupying 50% or more of a capacity of the contact hole may be defined as a contact plug.

Additionally, in Embodiments described above, the surface layer of the insulating film 20 is configured of the BPSG film 24 whereas the lower layer of the insulating film 20 is configured of the NSG film 22. However, an entire insulating film 20 may be configured of a BPSG film. That is, in the insulating film 20, a surface layer is preferably the BPSG film, however, a lower layer may be a BPSG film or another insulating film Additionally, in Embodiment described above, the surface layer of the insulating film 80 is configured of the BPSG film 24 whereas the lower layer of the insulating film 80 is configured of the NSG film 22 and the surface oxide film 17. However, an entire insulating film 80 may be configured of a BPSG film. That is, in the insulating film 80, the surface layer is preferably the BPSG film, however, the lower layer may be the BPSG film or another insulating film.

A semiconductor device disclosed herein as an example, comprises a semiconductor substrate, a first insulating film, a contact plug, a first surface electrode, a conductive layer, a second insulating film, a side metal layer, and a second surface electrode. The first insulating film is located on the semiconductor substrate and comprises a first contact hole. The contact plug is located in the first contact hole. The first surface electrode extends from a position on the first insulating film to a position on the contact plug. The conductive layer is located above a surface of the semiconductor substrate or in a semiconductor region within the semiconductor substrate. The second insulating film is located on the conductive layer and comprises a second contact hole having a width wider than that of the first contact hole. The side metal layer covers a corner portion between a side surface of the second contact hole and a bottom surface of the second contact hole. The side metal layer is configured of a same kind of metal as the contact plug. The second surface electrode extends from a position on the second insulating film to a position in the second contact hole, covers the side metal layer, and is configured of a different kind of metal from the contact plug. A bonding pad is located in a part of the second surface electrode on the bottom surface of the second contact hole.

In a semiconductor device disclosed herein as an example, a thickness of the side metal layer may increase from an upper side to a lower side of the side surface.

“The thickness of the side metal layer” described above means a dimension of the side metal layer when measured along a direction perpendicular to the side surfaces described above. In this configuration, the second surface electrode on the side metal layer can be formed to be flatter. Thus, the strength of the second surface electrode can be improved.

A semiconductor device disclosed herein as an example may further comprise a third insulating film located on the semiconductor substrate. In this case, the conductive layer may be located on the third insulating film.

A semiconductor device disclosed herein as an example may further comprise a first surface electrode extending from a position on the first insulating film to a position on the contact plug. The first surface electrode may be configured of the same kind of metal as the second surface electrode.

In this configuration, the first and second surface electrodes can be formed simultaneously. If a surface on which a metal layer is to be formed has recesses and projections, the metal layer has to be formed at a high temperature in order to develop the metal layer successfully. In contrast, the surface on which the first surface electrode is to be formed (i.e., the surface composed of the respective surfaces of the first insulation layer and contact plugs) is flat. Additionally, the level difference on the outer peripheral edges of the second contact hole is smoothly connected by the side metal layer. Accordingly, even in a case where a temperature at which the first and second surface electrodes are formed is relatively low, the first and second surface electrodes can be formed appropriately. Forming the first and second surface electrodes at a low temperature can further enhance the strengths of these electrodes. That is, the structure of this semiconductor device makes it possible to acquire the first and second surface electrodes of high strength.

In a semiconductor device disclosed herein as an example, a barrier metal may be interposed between the contact plug and the semiconductor substrate and between the side metal layer and the conductive layer.

In a semiconductor device disclosed herein as an example, at least a surface part of the second insulating film may be a BPSG film, and the second surface electrode is directly in contact with the BPSG film.

In this configuration, the first surface electrode is made further less liable to be peeled away.

In a semiconductor device disclosed herein as an example, the contact plug and the side metal layer may be configured of tungsten.

Embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. A semiconductor device, comprising:
a semiconductor substrate;
a first insulating film located on the semiconductor substrate and comprising a first contact hole;
a contact plug located in the first contact hole;
a first surface electrode extending from a position on the first insulating film to a position on the contact plug;
a conductive layer located above a surface of the semiconductor substrate or in a semiconductor region within the semiconductor substrate, the semiconductor region being exposed on the surface of the semiconductor substrate, and the surface of the semiconductor substrate including an area on which the first insulating film is located;
a second insulating film located on the conductive layer and comprising a second contact hole having a width wider than that of the first contact hole;
a side metal layer covering a corner portion between a side surface of the second contact hole and a bottom surface of the second contact hole, and configured of a same kind of metal as the contact plug; and
a second surface electrode extending from a position on the second insulating film to a position in the second contact hole, covering the side metal layer, and configured of a different kind of metal from the contact plug;
wherein a bonding pad is located in a part of the second surface electrode on the bottom surface of the second contact hole.

2. The semiconductor device of claim 1, wherein a thickness of the side metal layer increases from an upper side to a lower side of the side surface.

3. The semiconductor device of claim 1, further comprising a third insulating film located on the semiconductor substrate,
wherein the conductive layer is located on the third insulating film.

4. The semiconductor device of claim 1, wherein the first surface electrode is configured of a same kind of metal as the second surface electrode.

5. The semiconductor device of claim 1, wherein a barrier metal is interposed between the contact plug and the semiconductor substrate and between the side metal layer and the conductive layer.

6. The semiconductor device of claim 5, wherein
at least a surface part of the second insulating film is a BPSG film, and
the second surface electrode is directly in contact with the BPSG film.

7. The semiconductor device of claim 1, wherein the contact plug and the side metal layer are configured of tungsten.

8. A method for manufacturing a semiconductor device, comprising:
forming a conductive layer above a surface of a semiconductor substrate or in a semiconductor region in the semiconductor substrate, the semiconductor region being exposed on the surface of the semiconductor substrate;
forming a first insulating film on the surface of the semiconductor substrate in a range outside the conductive layer;
forming a second insulating film on the conductive layer;
forming a first contact hole in the first insulating film;
forming a second contact hole having a width wider than that of the first contact hole in the second insulating film;
forming a metal layer on the first insulating film, in the first contact hole, on the second insulating film and in the second contact hole;
etching the metal layer so that a part of the metal layer remains at a corner potion between a side surface of the second contact hole and a bottom surface of the second contact hole and another part of the metal layer remains in the first contact hole;
forming a first surface electrode extending from a position on the first insulating film to a position on the contact plug; and
forming a second surface electrode extending from a position on the second insulating film to a position in the second contact hole and covering the part of the metal layer at the corner portion.
